(19) United States
(12) Patent Application Publication
(10) Pub. No.: US 2026/0157011 A1
(43) Pub. Date: Jun. 4, 2026

(54) DISPLAY DEVICE

(71) Applicant: LG Display Co., Ltd., Seoul (KR)

(72) Inventors: Soojin Kim, Incheon (KR); Jaemin Park, Ansan-si (KR)

(73) Assignee: LG Display Co., Ltd., Seoul (KR)

(21) Appl. No.: 19/300,573

(22) Filed: Aug. 14, 2025

(30) Foreign Application Priority Data
Nov. 29, 2024 (KR) 10-2024-0175092

(51) Int. Cl. H10H 29/856; H10H 29/49; H10H 29/80

(52) U.S. Cl. CPC H10H 29/856; H10H 29/49; H10H 29/8325

(57) ABSTRACT

The present disclosure provides a display device including: a substrate; a reflective electrode disposed on the substrate; a light-emitting element disposed on the reflective electrode; a planarization layer disposed to cover the reflective electrode and the light-emitting element and including a trench; and a second connection electrode disposed on the planarization layer and the light-emitting element, in which the second connection electrode adjoins the reflective electrode in the trench. Therefore, the reflective electrode and the second connection electrode may be disposed to entirely surround the side surface and the bottom surface of the light-emitting element, thereby reflecting the light, which is emitted from the light-emitting element, in the upward direction of the light-emitting element, and improving the light extraction efficiency.

### CROSS-REFERENCE TO RELATED APPLICATIONS

This application claims the priority of Korean Patent Application No. 10-2024-0175092 filed on Nov. 29, 2024, in the Korean Intellectual Property Office, the disclosure of which is incorporated herein by reference in its entirety.

### BACKGROUND

### Technical Field

The present disclosure relates to a display device, and more particularly, to a display device using a light-emitting diode (LED).

### Discussion of the Related Art

As display devices used for a monitor of a computer, a TV set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED may be quickly turned on or off, have excellent luminous efficiency, high impact resistance, and great stability, and display high-brightness images.

### SUMMARY

Accordingly, embodiments of the present disclosure are directed to a display device that substantially obviates one or more of the problems due to limitations and disadvantages of the related art.

An aspect of the present disclosure is to provide a display device that includes an inorganic light-emitting element with improved luminous efficiency, such that the display device may operate with low power consumption.

Another aspect of the present disclosure is to provide a display device with improved light extraction efficiency.

Still another aspect of the present disclosure is to provide a display device capable of inhibiting or reducing light emitted from a light-emitting element from leaking to an adjacent subpixel or substrate.

Yet another aspect of the present disclosure is to provide a display device, in which a reflection structure is formed to surround the remaining portion of a light-emitting element, except for an upper portion of the light-emitting element, such that light emitted from the light-emitting element may be extracted in an upward direction.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate; a reflective electrode disposed on the substrate; a light-emitting element disposed on the reflective electrode; a planarization layer disposed to cover the reflective electrode and the light-emitting element and including a trench; and a second connection electrode disposed on the planarization layer and the light-emitting element, in which the second connection electrode adjoins the reflective electrode in the trench. Therefore, the reflective electrode and the second connection electrode may be disposed to entirely surround the side surface and the bottom surface of the light-emitting element, thereby reflecting the light, which is emitted from the light-emitting element, in the upward direction of the light-emitting element, and improving the light extraction efficiency.

Other detailed matters of the exemplary embodiments are included in the detailed description and the drawings.

According to the present disclosure, the display device includes the inorganic light-emitting element with excellent luminous efficiency, which may implement a high-resolution display device capable of displaying images with high efficiency and high luminance while operating with low power consumption.

According to the present disclosure, the reflection structure is formed to surround the remaining portion excluding the upper portion of the light-emitting element, which may improve the light extraction efficiency.

According to the present disclosure, the reflection structure and the second connection electrode are formed to surround the bottom surface and the side surface of the light-emitting element, which may inhibit or reduce the light emitted from the light-emitting element from leaking toward the adjacent subpixel or substrate.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a schematic configuration view of a display device according to an embodiment of the present disclosure;

FIG. 2 is an enlarged top plan view of the display device according to the embodiment of the present disclosure;

FIG. 3 is a cross-sectional view of a subpixel taken along line A-A′ in FIG. 2; and

FIG. 4 is a cross-sectional view of the subpixel taken along line B-B′ in FIG. 2.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to the drawings.

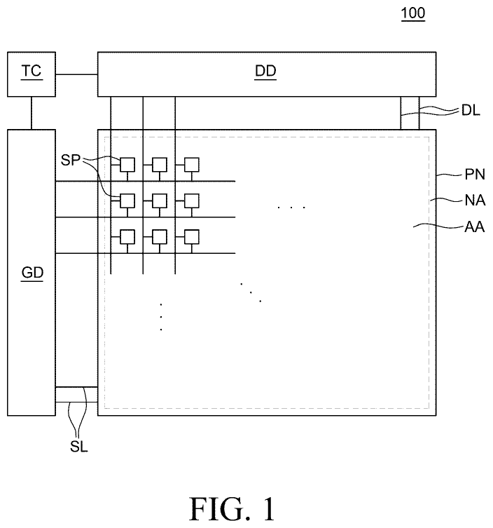

FIG. 1 is a schematic configuration view of a display device according to an embodiment of the present disclosure. For convenience of description, FIG. 1 illustrates only a display panel PN, a gate driver GD, a data driver DD, and a timing controller TC among various constituent elements of a display device 100.

With reference to FIG. 1, the display device 100 includes the display panel PN including a plurality of subpixels SP, the gate driver GD configured to supply various types of signals to the display panel PN, the timing controller TC configured to control the data driver DD and the gate driver GD, and the data driver DD.

The gate driver GD supplies a plurality of scan signals to a plurality of scan lines SL in response to a plurality of gate control signals provided from the timing controller TC. FIG. 1 illustrates that the single gate driver GD is disposed to be spaced apart from one side of the display panel PN. However, the number and arrangement of the gate driver GD are not limited thereto.

The data driver DD supplies data voltages to a plurality of data lines DL in response to a plurality of data control signals and image data provided from the timing controller TC. The data driver DD may convert image data into data voltages by using a reference gamma voltage and supply the converted data voltages to the plurality of data lines DL.

The timing controller TC aligns image data, which are inputted from the outside, and supplies the image data to the data driver DD. The timing controller TC may generate the gate control signals and the data control signals by using synchronizing signals, i.e., dot clock signals, data enable signals, and horizontal/vertical synchronizing signals inputted from the outside. Further, the timing controller TC may control the gate driver GD and the data driver DD by supplying the generated gate control signals and data control signals to the gate driver GD and the data driver DD.

The display panel PN is configured to display images to a user and includes the plurality of subpixels SP. In the display panel PN, the plurality of scan lines SL and the plurality of data lines DL may intersect one another, and the plurality of subpixels SP may be formed at intersection points between the scan line SL and the data line DL.

A display area AA and a non-display area NA may be defined on the display panel PN.

The display area AA is an area of the display device 100 in which images are displayed. The plurality of subpixels SP and a pixel circuit for operating the plurality of subpixels SP may be disposed in the display area AA. The plurality of subpixels SP may be minimum units that constitute the display area AA. The plurality of subpixels SP may each include a light-emitting element 120 and independently emit light. The plurality of subpixels SP may include a red subpixel SPR, a green subpixel SPG, a blue subpixel SPB, and the like and display images with various colors. The types of subpixels SP are illustrative. However, the embodiments of the present disclosure are not limited thereto.

A plurality of signal lines for transmitting various types of signals to the plurality of subpixels SP are disposed in the display area AA. For example, the plurality of signal lines may include the plurality of data lines DL for supplying data voltages to the plurality of subpixels SP, and the plurality of scan lines SL for supplying scan signals to the plurality of subpixels SP. The plurality of scan lines SL may extend in one direction in the display area AA and be connected to the plurality of subpixels SP. The plurality of data lines DL may extend in a direction different from one direction in the display area AA and be connected to the plurality of subpixels SP.

The non-display area NA may be defined as an area in which no image is displayed, i.e., an area extending from the display area AA. The non-display area NA may include link lines and pad electrodes for transmitting signals to the subpixels SP in the display area AA. Alternatively, the non-display area NA may include driver ICs such as gate driver ICs and data driver ICs.

Meanwhile, the non-display area NA may be positioned on a rear surface of the display panel PN, i.e., a surface on which the subpixel SP is not present. Alternatively, the non-display area NA may be excluded. However, the present disclosure is not limited to the configuration illustrated in the drawings.

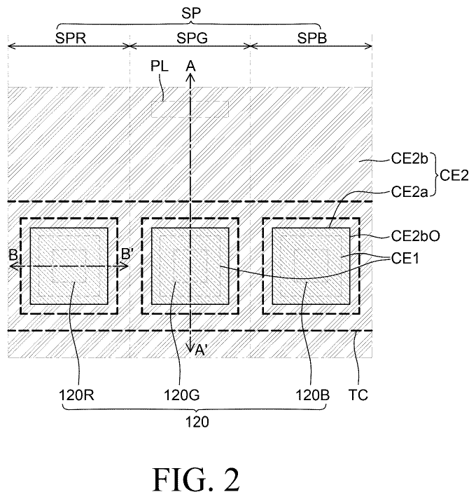

Hereinafter, the subpixel SP of the display panel PN of the display device 100 according to the embodiment of the present disclosure will be described more specifically with reference to FIGS. 2 to 4.

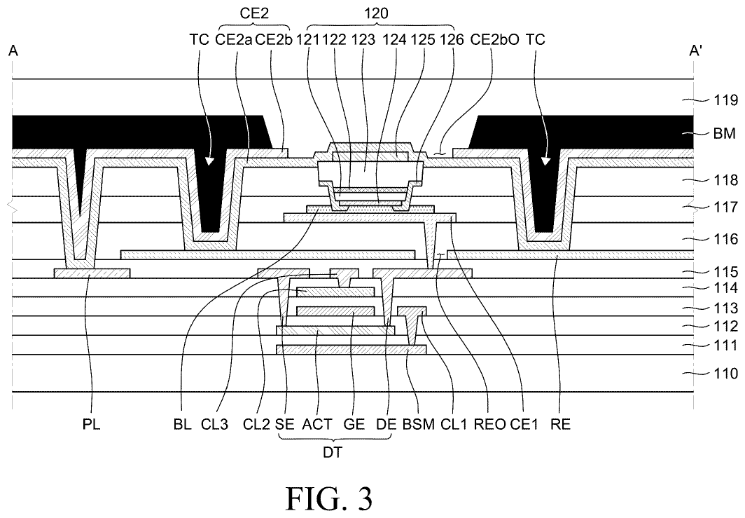

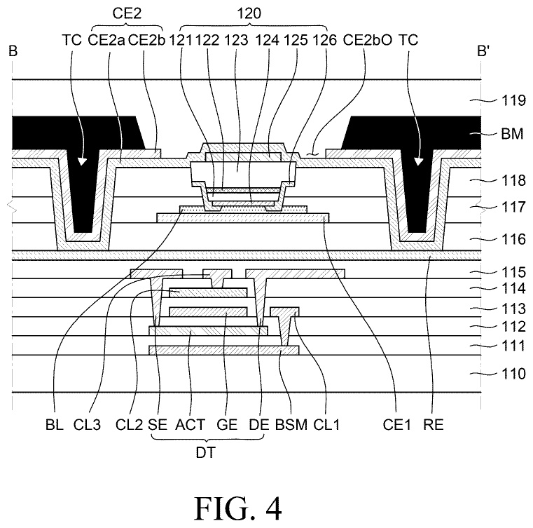

FIG. 2 is an enlarged top plan view of the display device according to the embodiment of the present disclosure. FIG. 3 is a cross-sectional view of a subpixel taken along line A-A′ in FIG. 2. FIG. 4 is a cross-sectional view of the subpixel taken along line B-B′ in FIG. 2. For convenience of description, FIG. 2 illustrates only the light-emitting elements 120, first connection electrodes CE1, second connection electrodes CE2, and a power line PL. In this case, the areas indicated by the bold dotted lines in FIG. 2 indicate trenches TC that surround each of the plurality of light-emitting elements 120.

With reference to FIGS. 2 to 4, the plurality of subpixels SP are disposed in the display area AA. The plurality of subpixels SP may each include the light-emitting element 120 and independently emit light. The plurality of subpixels SP may be disposed in a plurality of rows and a plurality of columns while defining a matrix shape. However, the embodiments of the present disclosure are not limited thereto.

The plurality of subpixels SP may include a red subpixel SPR, a green subpixel SPG, and a blue subpixel SPB. However, the types of subpixels SP are illustrative. However, the embodiments of the present disclosure are not limited thereto.

With reference to FIG. 3, a substrate 110 may be a member, i.e., an insulation substrate 110 configured to support other constituent elements of the display device 100. For example, the substrate 110 may be made of glass, resin, or the like. In addition, the substrate 110 may be made of polymer, plastic, or the like. In several embodiments, the substrate 110 may be made of a plastic material having flexibility.

A light-blocking layer BSM is provided on each of the plurality of subpixels SP and disposed on the substrate 110. The light-blocking layer BSM may block light entering an active layer ACT of a driving transistor DT, thereby minimizing a leakage current. The light-blocking layer BSM may be made of an opaque conductive material, for example, copper (Cu), aluminum (Al), molybdenum (Mo), nickel (Ni), titanium (Ti), chromium (Cr), or an alloy thereof. However, the present disclosure is not limited thereto.

A buffer layer 111 is disposed on the substrate 110 and the light-blocking layer BSM. The buffer layer 111 may be disposed to cover one surface of the substrate 110 and reduce the permeation of moisture or impurities through the substrate 110. For example, the buffer layer 111 may be configured as a single layer or multilayer made of silicon oxide (SiOx) or silicon nitride (SiNx). However, the present disclosure is not limited thereto.

The driving transistor DT is disposed on the buffer layer 111 in each of the plurality of subpixels SP. The driving transistor DT includes the active layer ACT, a gate electrode GE, a source electrode SE, and a drain electrode DE. Meanwhile, although not illustrated in the drawings, other constituent elements, such as a switching transistor, a sensing transistor, a light emission control transistor, and a storage capacitor may be additionally disposed in each of the plurality of subpixels SP, in addition to the driving transistor DT.

The active layer ACT of the driving transistor DT is disposed on the buffer layer 111. The active layer ACT may be made of a semiconductor material such as an oxide semiconductor, amorphous silicon, or polysilicon. However, the present disclosure is not limited thereto.

A gate insulation layer 112 is disposed on the active layer ACT. The gate insulation layer 112 is an insulation layer for insulating the active layer ACT and the gate electrode GE. For example, the gate insulation layer 112 may be configured as a single layer or multilayer made of silicon oxide (SiOx) or silicon nitride (SiNx). However, the present disclosure is not limited thereto.

The gate electrode GE is disposed on the gate insulation layer 112. The gate electrode GE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A first interlayer insulation layer 113 and a second interlayer insulation layer 114 are disposed on the gate electrode GE. The first interlayer insulation layer 113 and the second interlayer insulation layer 114 are insulation layers for protecting components disposed below the first interlayer insulation layer 113 and the second interlayer insulation layer 114. The first interlayer insulation layer 113 and the second interlayer insulation layer 114 may each be configured as a single layer or multilayer made of silicon oxide (SiOx) or silicon nitride (SiNx). However, the present disclosure is not limited thereto.

The source electrode SE and the drain electrode DE are disposed on the second interlayer insulation layer 114. The source electrode SE and the drain electrode DE may be electrically connected to the active layer ACT through contact holes formed in the first interlayer insulation layer 113, the second interlayer insulation layer 114, and the gate insulation layer 112. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A first line CL1 is disposed on the gate insulation layer 112. The first line CL1 may apply a constant voltage to the light-blocking layer BSM. For example, the light-blocking layer BSM may be connected to the first line CL1 and may not operate as a floating gate, thereby suppressing or reducing a change in threshold voltage of the driving transistor DT caused by the floating light-blocking layer BSM.

A second line CL2 is disposed on the first interlayer insulation layer 113, and a third line CL3 electrically connected to the second line CL2 is disposed on the second interlayer insulation layer 114. The second line CL2 and the third line CL3 may be disposed to overlap the gate electrode GE of the driving transistor DT and constitute a capacitor together with the gate electrode GE of the driving transistor DT. Therefore, various conductive layers, such as the second line CL2 and the third line CL3, are disposed on the substrate 110, thereby forming the capacitor.

The power line PL is disposed on the second interlayer insulation layer 114. The power line PL may be configured to transmit a power voltage to the light-emitting element 120 of each of the plurality of subpixels SP. The power line PL may be configured as any one of a low-potential power line PL or a high-potential power line PL depending on the configuration of the pixel circuit.

The first line CL1, the second line CL2, the third line CL3, and the power line PL may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

A passivation layer 115 is disposed on the driving transistor DT, the power line PL, and the second interlayer insulation layer 114. The passivation layer 115 is an insulation layer configured to cover and protect the pixel circuit including the driving transistor DT. The passivation layer 115 may include an inorganic insulating material, such as silicon oxide (SiOx) or silicon nitride (SiNx), and an organic insulating material, such as a benzocyclobutene or acrylic-based organic material. However, the present disclosure is not limited thereto.

As illustrated in FIG. 3, the power line PL may be disposed below the passivation layer 115. However, the present disclosure is not limited thereto. Like a reflective electrode RE to be described below, the power line PL may be disposed on the passivation layer 115 and made of the same material.

Next, the reflective electrode RE is disposed on the passivation layer 115 in each of the plurality of subpixels SP. The reflective electrode RE is disposed to overlap the light-emitting element 120. The reflective electrode RE may be disposed to at least extend from the light-emitting element 120 to the trench TC. The reflective electrode RE, together with the second connection electrode CE2 to be described below, may allow the light emitted from the light-emitting element 120 to propagate only in the upward direction of the light-emitting element 120. The reflective electrode RE may reflect the light beams that propagate in a downward direction of the light-emitting element 120 among the light beams emitted from the light-emitting element 120.

The reflective electrode RE includes an opening portion REO. The opening portion REO may overlap a contact hole through which the first connection electrode CE1, which is disposed above the reflective electrode RE, and the driving transistor DT, which is disposed below the reflective electrode RE, are electrically connected. The opening portion REO of the reflective electrode RE may be disposed to overlap the drain electrode DE of the driving transistor DT and the first connection electrode CE1. The opening portion REO of the reflective electrode RE may be smaller in size than the drain electrode DE. All the portions of the opening portion REO may be disposed to overlap the drain electrode DE. The drain electrode DE may be disposed to overlap the entire opening portion REO of the reflective electrode RE, which may minimize a leak of light that leaks toward the substrate 110 through the opening portion REO of the reflective electrode RE. The reflective electrode RE may be made of an opaque conductive material, such as silver (Ag), with high reflection efficiency.

A first planarization layer 116 is disposed on the reflective electrode RE. The first planarization layer 116 may planarize an upper portion of the reflective electrode RE. For example, the first planarization layer 116 may be made of a benzocyclobutene or acrylic-based organic material or the like. However, the present disclosure is not limited thereto.

The first connection electrode CE1 is disposed on the first planarization layer 116 in each of the plurality of subpixels SP. The first connection electrode CE1 is an electrode that electrically connects the light-emitting element 120 and the driving transistor DT. At least a part of the first connection electrode CE1 may overlap the opening portion REO of the reflective electrode RE.

A bonding layer BL is disposed on the first connection electrode CE1. The bonding layer BL may be a conductive joining member configured to fix the light-emitting element 120 to the first connection electrode CE1 and electrically connect the light-emitting element 120 and the first connection electrode CE1. The bonding layer BL may be made of a material having conductivity and bondability. For example, the bonding layer BL may be an organic layer made of a material including conductive particles such as indium or an organic layer including conductive particles such as carbon. However, the present disclosure is not limited thereto. In this case, the bonding layer BL may be made of a material that may be subjected to a photolithography process. The thickness or arrangement area of the bonding layer BL may be easily controlled by the photolithography process.

The light-emitting element 120 is disposed on the bonding layer BL in each of the plurality of subpixels SP. For example, the light-emitting element 120 may be any one of a light-emitting diode (LED) or a micro-light-emitting diode (micro-LED). However, the embodiments of the present disclosure are not limited thereto. The light-emitting elements 120 may include a red light-emitting element 120R of the red subpixel SPR, a green light-emitting element 120G of the green subpixel SPG, and a blue light-emitting element 120B of the blue subpixel SPB. Images with various colors may be displayed by a combination of the red light-emitting element 120R, the green light-emitting element 120G, and the blue light-emitting element 120B.

The light-emitting element 120 includes a first semiconductor layer 121, a light-emitting layer 122, a second semiconductor layer 123, a first electrode 124, a second electrode 125, and a protective film 126.

First, the first semiconductor layer 121 is disposed on the bonding layer BL, and the second semiconductor layer 123 is disposed on the first semiconductor layer 121. The first semiconductor layer 121 and the second semiconductor layer 123 may be semiconductor layers doped with p-type and n-type impurities. For example, the first semiconductor layer 121 and the second semiconductor layer 123 may be layers formed by doping materials, such as gallium nitride (GaN), indium aluminum phosphide (InAlP), or gallium arsenide (GaAs) with p-type and n-type impurities.

The light-emitting layer 122 is disposed between the first semiconductor layer 121 and the second semiconductor layer 123. The light-emitting layer 122 may emit light on the basis of a drive current supplied to the light-emitting element 120. The light-emitting layer 122 may be configured as a single layer or a multi-quantum well (MQW) structure. For example, the light-emitting layer 122 may be made of indium gallium nitride (InGaN), gallium nitride (GaN), or the like. However, the present disclosure is not limited thereto.

The first electrode 124 is disposed below the first semiconductor layer 121. The first electrode 124 may adjoin a bottom surface of the first semiconductor layer 121. The first electrode 124 of the light-emitting element 120 may be electrically connected to the driving transistor DT through the bonding layer BL and the first connection electrode CE1.

The second electrode 125 is disposed on the second semiconductor layer 123. The second electrode 125 may adjoin a top surface of the second semiconductor layer 123. The second electrode 125 of the light-emitting element 120 may be electrically connected to the power line PL through the second connection electrode CE2.

The protective film 126 is disposed to surround at least a part of the first semiconductor layer 121, at least a part of the light-emitting layer 122, and at least a part of the second semiconductor layer 123. The protective film 126 may protect the first semiconductor layer 121, the light-emitting layer 122, and the second semiconductor layer 123. The first electrode 124 and the second electrode 125 may be exposed from the protective film 126 and connected to the first connection electrode CE1 and the second connection electrode CE2. For example, the protective film 126 may be made of an insulating material such as silicon oxide (SiOx) or silicon nitride (SiNx). However, the present disclosure is not limited thereto.

A second planarization layer 117 is disposed on the light-emitting element 120, and a third planarization layer 118 is disposed on the second planarization layer 117. The second planarization layer 117 and the third planarization layer 118 may each be configured as a single layer or multilayer and made of a benzocyclobutene or acrylic-based organic material, for example. However, the present disclosure is not limited thereto.

The second connection electrode CE2 is disposed on the third planarization layer 118. The second connection electrode CE2 is an electrode that electrically connects the light-emitting element 120 and the power line PL. In addition, the second connection electrode CE2 may be an electrode configured to reflect the light beams, which propagate toward the side surface among the light beams emitted from the light-emitting element 120, toward an upper portion of the light-emitting element 120. The second connection electrode CE2 may have a multilayer structure including a first conductive layer CE2a and a second conductive layer CE2b.

The first conductive layer CE2a is formed in an entire area of the second connection electrode CE2. The first conductive layer CE2a may be made of a transparent conductive material such as indium tin oxide (ITO) or indium zinc oxide (IZO). Therefore, the light emitted from the light-emitting element 120 may pass through the first conductive layer CE2a and propagate toward the upper portion of the light-emitting element 120.

The second conductive layer CE2b is disposed on the first conductive layer CE2a. The second conductive layer CE2b may be made of an opaque conductive material such as silver (Ag), nickel (Ni), gold (Au), platinum (Pt), aluminum (Al), molybdenum (Mo), titanium (Ti), or an alloy thereof. Therefore, some of the light beams, which propagate in another direction instead of the upward direction of the light-emitting element 120 among the light beams emitted from the light-emitting element 120, may be reflected by the second conductive layer CE2b. In this case, an open area CE2bO, which is an opening portion, may be formed in the second conductive layer CE2b so that the light emitted from the light-emitting element 120 may propagate in the upward direction of the light-emitting element 120. Because only the first conductive layer CE2a made of a transparent conductive material is disposed in the open area CE2bO, the light emitted from the light-emitting element 120 may propagate toward the outside of the display device 100 through the open area CE2bO. The open area CE2bO may be disposed to overlap the light-emitting element 120. A width of the open area CE2bO may be larger than a width of the light-emitting element 120.

The trench TC is disposed in the first planarization layer 116, the second planarization layer 117, and the third planarization layer 118. The trench TC is a ‘V’-shaped hole formed in the first planarization layer 116, the second planarization layer 117, and the third planarization layer 118. With reference to FIG. 2, the trench TC may be disposed to surround each of the light-emitting elements 120. For example, the trenches TC may be disposed between the red subpixel SPR and the green subpixel SPG and between the green subpixel SPG and the blue subpixel SPB. In addition, the trenches TC may be disposed in upper and lower areas of each of the plurality of subpixels SP.

Meanwhile, the drawings illustrate that the trenches TC of the subpixels SP are connected to one another. However, the trenches TC of the subpixels SP may be disposed to be spaced apart from one another. However, the present disclosure is not limited thereto.

Because the trench TC is formed in the first planarization layer 116, the second planarization layer 117, and the third planarization layer 118, the second connection electrode CE2 formed on the third planarization layer 118 may also be disposed along the trench TC. The second connection electrode CE2 may adjoin the reflective electrode RE in the trench TC. The second connection electrode CE2 and the reflective electrode RE may be electrically connected to each other through the trench TC. Therefore, as illustrated in FIG. 2, the trench TC may have a shape that surrounds all the side surfaces of the light-emitting element 120. Therefore, the second connection electrode CE2 and the reflective electrode RE may have shapes that entirely surround the side surface and the lower portion of the light-emitting element 120. In this case, the reflective electrode RE and the second conductive layer CE2b of the second connection electrode CE2 may reflect and block all the light beams that propagate toward the substrate 110 or propagate toward the adjacent subpixel SP among the light beams emitted from the light-emitting element 120. The light may be extracted only in the upward direction of the light-emitting element 120. Therefore, the trench TC is formed to surround the light-emitting element 120, and the second connection electrode CE2 and the reflective electrode RE are connected in the trench TC, such that the light extraction efficiency of the light-emitting element 120 may be improved.

A black bank BM is disposed on the third planarization layer 118 and the second connection electrode CE2. The black bank BM may include an opening portion that overlaps the light-emitting element 120 and the open area CE2bO of the second conductive layer CE2b. The opening portion of the black bank BM may have a larger size than the open area CE2bO. However, the present disclosure is not limited thereto. The opening portion of the black bank BM may be equal in size to the open area CE2bO. The light, which is emitted from the light-emitting element 120, and the light, which is reflected by the second connection electrode CE2 and the reflective electrode RE, may propagate toward the outside of the display device 100 through the opening portion of the black bank BM. In addition, the black bank BM may block the light beams emitted from the plurality of subpixels SP, thereby inhibiting or reducing the colors of the light beams from being mixed. The black bank BM may absorb the light entering the display device 100 from the outside, thereby minimizing a deterioration in visibility caused when external light is reflected by the components in the display device 100. For example, the black bank BM may include a black component and be made of opaque resin or the like including pigment. However, the present disclosure is not limited thereto.

A protective layer 119 is disposed on the black bank BM. The protective layer 119 is a layer for protecting components disposed below the protective layer 119. The protective layer 119 may suppress or reduce the permeation of moisture or oxygen from the outside. For example, the protective layer 119 may be configured as a single layer or multilayer and made of epoxy-based polymer or acrylic-based polymer, for example. However, the present disclosure is not limited thereto.

Therefore, in the display device 100 according to the embodiment of the present disclosure, the trench TC is formed to surround the light-emitting element 120, the trench TC has a shape that surrounds all the side surfaces of the light-emitting element 120, and the second connection electrode CE2 and the reflective electrode RE are connected in the trench TC, such that the light may be discharged to the open area CE2bO without being discharged to the lower portion of the substrate 110 or the adjacent subpixel SP, thereby improving the light extraction efficiency. The trench TC may be disposed in a shape that surrounds the light-emitting element 120, and the opaque second conductive layer CE2b disposed in the trench TC may reflect the light and inhibit or reduce the light emitted from the light-emitting element 120 from leaking to the adjacent subpixel SP, thereby further improving the light extraction efficiency. In addition, the trench TC is formed up to the reflective electrode RE, such that the reflective electrode RE and the second connection electrode CE2 may be connected to each other, and may block the light emitted from the light-emitting element 120 from being discharged to the lower portion of the substrate 110. Therefore, at least a part of the light reflected by the second connection electrode CE2 and the reflective electrode RE may propagate toward the upper portion of the light-emitting element 120, such that the light extraction efficiency and display quality of the display device 100 may be improved.

In the display device 100 according to the embodiment of the present disclosure, the second connection electrode CE2 has the multilayer structure including the transparent first conductive layer CE2a and the opaque second conductive layer CE2b, such that the second connection electrode CE2 may be used as an electrode configured to electrically connect the light-emitting element 120 and the power line PL and as a reflective plate configured to reflect the light emitted from the light-emitting element 120. The transparent first conductive layer CE2a may be formed in the entire area of the second connection electrode CE2 and electrically connect the light-emitting element 120 and the power line PL. In particular, only the first conductive layer CE2a is disposed in the open area CE2bO, such that the light emitted from the light-emitting element 120 may easily propagate to the outside of the display device 100. In addition, the opaque second conductive layer CE2b may be disposed in the remaining area excluding the open area CE2bO and used as a reflective plate configured to reflect the light emitted from the light-emitting element 120. Therefore, the second connection electrode CE2 may be configured as the multilayer structure, and the second connection electrode CE2 may be used as the reflective plate, which may improve the light extraction efficiency of the display device 100.

The exemplary embodiments of the present disclosure can also be described as follows:

According to an aspect of the present disclosure, a display device includes a substrate, a reflective electrode disposed on the substrate, a light-emitting element disposed on the reflective electrode, a planarization layer disposed to cover the reflective electrode and the light-emitting element and comprising a trench, and a second connection electrode disposed on the planarization layer and the light-emitting element, wherein the second connection electrode adjoins the reflective electrode in the trench.

The trench may be disposed to surround all side surfaces of the light-emitting element.

The second connection electrode may include a transparent first conductive layer, and an opaque second conductive layer disposed on the first conductive layer.

The second conductive layer may include an open area that overlaps the light-emitting element.

The first conductive layer may be disposed in an entire area of the second connection electrode, and the second conductive layer may be disposed in a remaining area of the entire area of the second connection electrode that excludes the open area.

The reflective electrode and the second connection electrode may be disposed to surround a side surface and a bottom surface of the light-emitting element.

The display device may further include a black bank disposed on the second connection electrode and having an opening portion that overlaps the open area and the light-emitting element, and the opening portion of the black bank may have a size larger than or equal to the open area.

The display device may further include a power line disposed on the substrate, a driving transistor disposed between the substrate and the reflective electrode, and a first connection electrode disposed between the reflective electrode and the light-emitting element. The driving transistor may be electrically connected to the light-emitting element through the first connection electrode, and the power line may be electrically connected to the light-emitting element through the second connection electrode.

The reflective electrode may include an opening portion that overlaps the first connection electrode and the driving transistor, and a contact hole through which the first connection electrode and the driving transistor are electrically connected may overlap the opening portion.

A size of the opening portion of the reflective electrode may be smaller than a size of a drain electrode of the driving transistor.

A drain electrode of the driving transistor may overlap the entire opening portion of the reflective electrode.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate;
a reflective electrode disposed on the substrate;
a light-emitting element disposed on the reflective electrode;
a planarization layer disposed to cover the reflective electrode and the light-emitting element and comprising a trench; and
a second connection electrode disposed on the planarization layer and the light-emitting element,
wherein the second connection electrode adjoins the reflective electrode in the trench.

2. The display device of claim 1, wherein the trench is disposed to surround all side surfaces of the light-emitting element.

3. The display device of claim 1, wherein the second connection electrode comprises:
a transparent first conductive layer; and
an opaque second conductive layer disposed on the transparent first conductive layer.

4. The display device of claim 3, wherein the opaque second conductive layer comprises an open area that overlaps the light-emitting element.

5. The display device of claim 4, wherein the transparent first conductive layer is disposed in an entire area of the second connection electrode, and the opaque second conductive layer is disposed in a remaining area of the entire area of the second connection electrode that excludes the open area.

6. The display device of claim 4, wherein a width of the open area larger than a width of the light-emitting element.

7. The display device of claim 5, wherein the reflective electrode and the second connection electrode are disposed to surround a side surface and a bottom surface of the light-emitting element.

8. The display device of claim 4, further comprising:
a black bank disposed on the second connection electrode and having an opening portion that overlaps the open area and the light-emitting element,
wherein the opening portion of the black bank has a size larger than or equal to the open area.

9. The display device of claim 1, further comprising:
a power line disposed on the substrate;
a driving transistor disposed between the substrate and the reflective electrode; and
a first connection electrode disposed between the reflective electrode and the light-emitting element,
wherein the driving transistor is electrically connected to the light-emitting element through the first connection electrode, and
wherein the power line is electrically connected to the light-emitting element through the second connection electrode.

10. The display device of claim 9, wherein the reflective electrode comprises an opening portion that overlaps a contact hole through which the first connection electrode and the driving transistor are electrically connected.

11. The display device of claim 10, wherein a size of the opening portion of the reflective electrode is smaller than a size of a drain electrode of the driving transistor.

12. The display device of claim 11, wherein the drain electrode of the driving transistor overlaps an entirety of the opening portion of the reflective electrode.
